(19) United States
(12) Patent Application Publication
(10) Pub. No.: US 2005/0106507 A1
(43) Pub. Date: May 19, 2005

(54) Device and method for laser structuring functional polymers and the use thereof

(76) Inventors: Adolf Bernds, Baiersdorf (DE); Wolfgang Clemens, Puschendorf (DE); Hans-Klaus Roth, Laasen (DE); Mario Schrodner, Rudolstadt (DE); Ralf-Ingo Stohn, Jena (DE)

Correspondence Address: Carella Byrne Bain Gilfillan, 5 Becker Farm Road, Roseland, NJ, 07068, US

(21) Appl. No.: 10/508,737

(22) PCT Filed: Mar. 12, 2003
(86) PCT No.: PCT/DE03/00791

(30) Foreign Application Priority Data
Mar. 21, 2002 (DE) 102 12 639.9

(51) Int. Cl. G03F 7/20

(52) U.S. Cl. 430/322; 430/397; 355/18

(57) ABSTRACT

The invention relates to a device and process for laser structuring and applications thereof in the production of semiconductors.

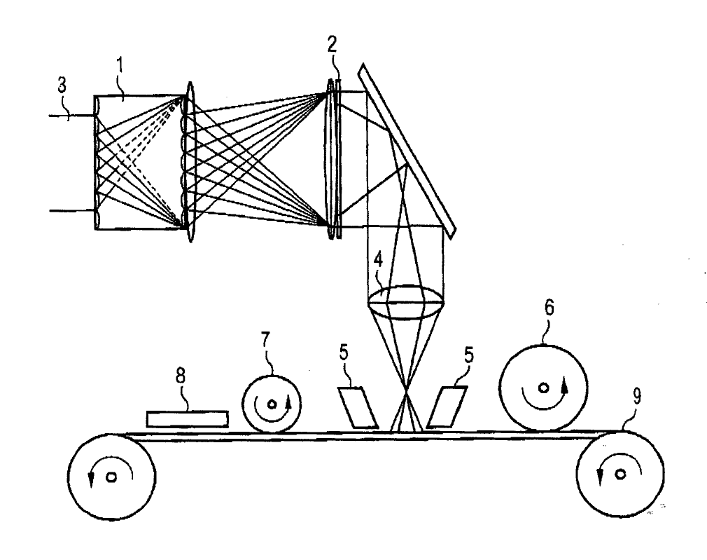

The invention relates to a device and process for laser structuring and applications thereof in the production of semiconductors.

Essentially two methods are known for structuring organic functional polymers: photo-lithography, which necessitates piece-by-piece processing, and continuous printing processes.

DE 100 33 112, DE 100 43 204 and DE 100 61 297 disclose continuous printing processes for structuring organic functional polymers. However, these fast printing processes are as yet unable to achieve the high resolution obtainable using photolithographic structuring methods.

It is therefore an object of the invention to provide a process for continuous structuring of functional polymers, in which high structuring resolution can be achieved despite a high throughput rate of the functional polymer.

The present invention relates to a device for structuring a functional polymer, comprising at least one continuously moving web carrying a coated substrate, at least one laser and at least one mask situated between the laser and the substrate, laser, mask and substrate being disposed such that the coated substrate is bombarded by the laser through the mask such that the layer on the substrate is removed locally therefrom in conformity with the configuration of the mask. Another object of the invention is to provide a process for structuring functional polymers by means of at least one laser ablation step, in which, in a continuous working process, the image of said mask is projected by at least one laser pulse onto at least one continuous substrate coated with at least one functional polymer such that the functional polymer is locally removed in conformity with the configuration of said mask.

Finally, further objects of the invention are various applications relating to processes for the production of integrated circuits.

By “functional polymer” we mean an organic material that fulfils a function in a semi-conductor component (ie conductivity, non-conductivity, semi-conductivity, transparence, opacity, and/or insulation) or a combination of two or more functions.

The term “organic material” or “functional polymer” or “polymer” includes in this case all types of organic, organometallic, and/or organic-inorganic man-made materials (hybrids), particularly those referred to in the English language as, eg, “plastics”. All types of materials are suitable with the exception of the semiconductors forming classical diodes (germanium, silicon) and the typical metallic conductors. It is thus not intended to dogmatically confine organic material to that consisting of purely carbonaceous material, but rather the term also covers the wide use of, say, silicones. Furthermore, the term should not, with respect to molecular size, be particularly confined to polymeric and/or oligomeric materials but can also refer to the use of “small molecules”. The word component “polymer” in the term “functional polymer” is of historical origin and contains no inference to the presence of an actual polymeric compound,

The process of laser ablation as a method for the manufacture of structured layers of functional polymer is a direct lithographic process, in which laser bombardment combines both the effect of structuring by exposure and the dry etching process of the conventional photolithographic process. Laser structuring has hitherto been known only in conjunction with piece-by-piece processing in the production of semiconductors. According to the invention, the image of a mask is simultaneously projected onto the layer to be structured in a manner similar to that employed in photo-lithography.

The invention makes it possible, for the first time, to make use of laser ablation, ie the local removal of polymeric material due to laser bombardment, in a continuous process for the production of semiconductors.

Advantageously, the continuous process employed is a roller-to-roller process, in which a web carrying a coated substrate (substrate roll) is subjected at high speed to process steps such as printing, coating, etc., without having to stop for the ablation step.

In an advantageous embodiment, laser ablation is effected by a single laser pulse.

A single laser pulse of approximately 20 ns is so short that it produces sharp images even when the web travels at maximum speed, eg, 20 m/s. In the numerical example given here, the degree of unsharpness caused by the motion of the web is less than 1 nm. This is negligible compared with the desired structure sizes in the micron range.

This makes it clear that laser structuring is basically compatible with roll-to-roll processes. For the sake of clarification, it might be mentioned that the present process does not involve the frequently used sequential writing using a focused laser beam, which has its limits as regards speed and resolution, but involves laser pulses, which means that, in a manner similar to photolithography, the image of a mask is simultaneously projected onto the layer to be structured so that each laser pulse produces a complete integrated circuit.

According to one embodiment, the image of the mask is reduced by a factor of 5. In other words, the mask is typically 5 times larger than its projected image in order to decrease the power density in the mask, as otherwise the mask would itself be ablated.

According to one embodiment, laser ablation is combined with at least one suction device.

The process can replace all of the process steps involved in stereolithography during the production of semiconductors. In particular, the process can be used for:
Laser structuring electrodes (source/drain and gate) in organic field effect transistors.

These electrodes can comprise metals (eg, gold, aluminum, copper) or conductive polymers (eg, polyaniline and PEDOT/PSS, polypyrrole, polyacetylene, etc.) or other conductive, particularly organic, materials or composite materials (eg, conductive lamp black and pastes containing metals (eg, conductive silver)). For example the following conductive polymers are capably of being structured using laser: polyaniline (PANI); poly-3,4-ethylenedioxythiophene (PEDOT); polypyrrole (Ppy).

For source/drain electrodes it has been possible to achieve structure sizes down to 1 μm. In addition, ablation experiments on laminates have already been carried out.

The object of the procedure is to remove only the top layer without attacking the underlying layer. This can be achieved by adjusting the energy or power of the laser pulse, the wavelength of the laser light and the number of laser pulses. This is an important factor when structuring the gate electrode forming the top layer of the transistor structure.

Structuring of semiconductor and/or insulator layers. Examples of organic semiconductors are: polythiophenes, polyfluorenes, pentacene, perylene, etc. An example of an organic insulator is poly-4-vinylphenol or polyhydroxystyrene.

The production of through-connections (via holes) in organic transistors. In a transistor the electrodes (source/drain and gate) are separated from each other by the intermediate semiconductor and insulator layers. A connection between these two, as is necessary for the production of integrated circuits, can likewise be effected by laser structuring, ie by local pinpoint removal of the semiconductor and insulator layers followed by filling the hole with a conductive material,
Further applications of the process for the production of organic circuits are:
conducting paths, contact pads, resistors, electrodes, semi-conducting layers, insulator layers for other electronic organic components, eg, for condensers, organic diode structures or organic photovoltaic structures.

The invention is explained below with reference to the drawing:

The drawing shows an embodiment of a system for laser structuring of functional polymers in a roll-to-roll process together with other devices for producing and treating layers. It shows a laser 1 with optics. Preferably, lasers are used which emit in the ultraviolet spectral region (ca 100 to 350 nm). Typically, the laser is an excimer laser. The optics serve to widen the laser beam. Laser beam 3 then passes through mask 2. The image of a mask 2 in the optical path 3 ensures that not the complete layer of functional polymer but rather specific areas thereof are removed so that precisely the desired shape of the electrodes or conducting paths remains. The laser beam has preferably a greater cross-section at the mask so as to protect the mask from being damaged. For this reason, optics 4 are required so that a reduced image of the mask is projected onto the layer of functional polymer.

Optics 4 guide the beam onto the substrate roll 9 to be structured, eg, a coated substrate. Now the action of the laser beam 3 causes part of a layer of functional polymer disposed on the substrate roll 9 to be locally removed. The functional polymer remaining on the substrate roll 9 then forms, say, electrodes and/or conducting paths, etc., when the functional polymer is a conductive functional polymer. The functional polymer is removed as in a dry etching process. The system outlined contains a suction device 5, since it is to be expected that the laser ablation will produce degradation products.

Furthermore, there are provided before and after the laser ablation area, as regarded in the direction of travel of the substrate, devices for the production and treatment of a coating 6 and/or printing devices 7. Thus the device 6 may be, say, a coating unit that produces a complete layer, which is then laser-structured. The device 7 can be, say, a printing unit that applies another structured layer by a printing process. It may then be necessary, under certain circumstances, to dry the printed layer, for which purpose drying equipment 8 is proposed. The embodiment shown can be arbitrarily modified and expanded, and, in particular, it is conceivable to operate with a number of in-line and/or parallel laser structuring steps. Thus a first laser might effect electrode structuring, whilst, after the application of another layer, a second laser could produce the through-connections (via holes).

Laser structuring combines two advantages. Firstly, as shown above, it is roll-to-roll compatible and thus allows for maximum production rates. Secondly, it has a very high resolving power. At present there exists no other process for semiconductor structuring that combines these two advantages, neither photolithography nor printing processes nor any other methods. Furthermore, laser structuring can be combined with other roll-to-roll processes such as printing processes.

1. A device for structuring a functional polymer, comprising at least one continuously moving web carrying a coated substrate, the coating forming a layer on the substrate, at least one laser for generating a beam and a mask, the laser, mask and substrate being disposed such that said coated substrate is bombarded by said laser beam through said mask such that the layer on said substrate is removed locally therefrom in conformity with the configuration of said mask.

2. A device as defined in claim 1, wherein said laser emits the beam in the ultraviolet spectral region.

3. A device as defined in any one of the previous claims, wherein said laser is an excimer laser.

4. A device as defined in any one of claims 1 and 2, including a suction device for removing debris from said substrate.

5. A process for structuring functional polymers by at least one laser ablation step, wherein, in a continuous working process, the image of a mask is projected by at least one laser pulse onto a continuous substrate coated with at least one functional polymer such that said functional polymer is locally removed in conformity with the configuration of said mask.

6. A process as defined in claim 5, wherein said continuous working process is a roller-to-roller process.

7. a process as defined in claim 5 or claim 6, wherein said laser ablation is effected by a single laser pulse.

8. A process as defined in any one of claims 5 or 6, wherein the projected image of said mask is reduced by a factor of 5.

9. A method of using a device as defined in any one of claims 1 or 2 and/or of using a process as defined in any one of claims 5 or 6 for laser structuring electrodes, for structuring semiconductor and/or insulator layers, for making through-connections (via holes) of organic transistors and/or for the production of conducting paths, contact pads, resistors, electrodes, semi-conducting layers, insulator layers for electronic and/or electrical components, for condensers, organic diode structures, or organic photovoltaic structures.
